(19) United States
(12) Patent Application Publication
(10) Pub. No.: US 2025/0185166 A1
(43) Pub. Date: Jun. 5, 2025

(54) Metal-ceramic substrate and method of manufacturing a metal-ceramic substrate

(71) Applicant: Rogers Germany GmbH, Eschenbach (DE)

(72) Inventors: Tilo Welker, Neuhaus (DE); Stefan Britting, Schnaittach (DE); Fabian Wagle, Bayreuth (DE); Andreas Meyer, Speichersdorf (DE); Karsten Schmidt, Eschenbach (DE)

(21) Appl. No.: 18/840,337

(22) PCT Filed: Jan. 27, 2023
(86) PCT No.: PCT/EP2023/051984

§ 371 Date: Aug. 21, 2024

(30) Foreign Application Priority Data
Feb. 22, 2022 (DE) 10 2022 104 156.5

(51) Int. Cl. H05K 1/11; H05K 1/03; H05K 3/40

(52) U.S. Cl. CPC H05K 1/115; H05K 1/0306; H05K 3/4038

(57) ABSTRACT

A metal-ceramic substrate (1) as a carrier for electrical components, in particular in the form of a printed circuit board, comprising
a ceramic element (20) and
at least one metal layer (10, 20), wherein the at least one metal layer (10) and the ceramic element (30) extend along a main extension plane (HSE) and are arranged on top of one another along a stacking direction(S) running perpendicular to the main extension plane (HSE),
   wherein a bonding layer (12) is formed in the manufactured metal-ceramic substrate (1) between the at least one metal layer (10, 20) and the ceramic element (30), and
   wherein a bonding agent layer of the bonding layer (12) has a sheet resistance which is greater than 5 ohm/sq, more preferably greater than 10 ohm/sq and most preferably greater than 20 ohm/sq, wherein an interconnection (15) is formed in the ceramic element (30).

### CROSS REFERENCE TO RELATED APPLICATIONS

This application is a National Stage application of PCT/EP2023/051984, filed on Jan. 27, 2023, which claims the benefit of German Application No. DE 10 2022 104 156.5, filed on Feb. 22, 2022, both of which are incorporated by reference in their entirety herein.

### BACKGROUND

The present invention relates to a metal-ceramic substrate and a method of manufacturing a metal-ceramic substrate.

Carrier substrates for electrical components, for example in the form of metal-ceramic substrates, are sufficiently known from the prior art, for example as printed circuit boards or circuit boards, for example from DE 10 2013 104 739 A1, DE 19 927 046 B4 and DE 10 2009 033 029 A1. Typically, connecting areas for electrical components and conductor paths are arranged on one component side of the metal-ceramic substrate, wherein the electrical components and conductor paths can be interconnected to form electrical circuits. Essential components of the metal-ceramic substrates are an insulating layer, which is more preferably made of a ceramic, and a component metallisation or component metallisation bonded to the insulating layer. Due to their comparatively high insulation strength, insulating layers made of ceramic have proven to be particularly advantageous in power electronics. By structuring the component metallisation, conductor paths and/or connecting areas for the electrical components can then be realised.

Furthermore, it is common practice to provide interconnections with which the component metallisation and a backside metallization or a metallic intermediate layer can be joined together on the metal-ceramic substrate in order to enable electrical contact.

The present invention sets itself the object of improving the metal-ceramic substrates with interconnections known from the prior art, in particular with regard to the effort required to manufacture the interconnection.

### SUMMARY

The present invention achieves the object by means of metal-ceramic substrates as described herein and a method of manufacturing them as described herein. Further advantageous embodiments are apparent from the description and the figures.

According to a first aspect of the present invention, a metal-ceramic substrate is provided as a carrier for electrical components, in particular in the form of a printed circuit board, comprising
a ceramic element and
at least one metal layer, wherein the at least one metal layer and the ceramic element extend along a main extension plane and are arranged on top of one another along a stacking direction running perpendicular to the main extension plane,
   wherein a bonding layer is formed in the manufactured metal-ceramic substrate between the at least one metal layer and the ceramic element,
   wherein a bonding agent layer of the bonding layer has a sheet resistance which is greater than 5 ohm/sq, more preferably greater than 10 ohm/sq and most preferably greater than 20 ohm/sq, and wherein an interconnection is formed in the ceramic element.

### BRIEF DESCRIPTION OF THE DRAWINGS

Further advantages and features result from the following description of preferred embodiments of the subject-matter according to the invention with reference to the attached figures. Individual features of the individual embodiments can be combined with each other within the scope of the invention.

It is shown in:

FIG. 1 a metal-ceramic substrate with an interconnection according to the prior art,

FIG. 2 a metal-ceramic substrate according to a first exemplary embodiment of the present invention in a sectional view

FIG. 3 a metal-ceramic substrate according to a second exemplary embodiment of the present invention in a sectional view

FIGS. 4a to 4e cross-sectional areas of recesses in the ceramic element,

FIGS. 5a to 5g side surfaces of the recess in the ceramic element and

FIGS. 6a to 6c arrangements of interconnections.

### DETAILED DESCRIPTION

In contrast to the metal-ceramic substrates provided in the prior art, the metal-ceramic substrate according to the invention has a sheet resistance which is comparatively large. This is due to certain manufacturing processes in which—in particular with the use of a separate and comparatively thin active metal layer—a bonding of the at least one metal layer to the ceramic element is utilised. The at least one metal layer can be a component metallisation, a backside metallization and/or an intermediate metallisation of the metal-ceramic substrate. It has been shown that it is advantageously possible to realise the interconnection at the same time as the bonding between the at least one metal layer and the ceramic element using the selected manufacturing process, so that no additional time-consuming work step is required. The manufacturing process is reflected in the metal-ceramic substrate produced by the sheet resistance generated.

The interconnection is preferably embedded in a recess in the ceramic element or at least partially fills the recess. The recess preferably extends from the upper side of the ceramic element to the bottom side of the ceramic element, wherein the component metallisation is bonded to the upper side and the backside metallization is bonded to the bottom side of the ceramic element. Preferably, the bonding layer is also formed in a recess of the ceramic element or the bonding layer extends into a recess of the ceramic element. The interconnection is formed within the recess in the finished state.

During the bonding process, an active metal layer in use becomes the bonding layer or part of the bonding layer. Together with other parameters, such as the thickness of the bonding layer, the purity of the applied active metal layer and/or the roughness of the ceramic element, this contributes to a correspondingly formed sheet resistance. To determine the sheet resistance, it is provided that the at least one metal layer and, if necessary, a solder base layer are first removed from the manufactured carrier substrate, for example by etching. By means of a four-point measurement, a sheet resistance is then measured on the upper side or bottom side of the carrier substrate freed from the at least one metal layer and the solder base layer. In particular, the sheet resistance of a material sample is to be understood as its resistance in relation to a square surface area. It is customary to characterise the surface resistance with the unit ohm/sq (square). The physical unit of sheet resistance is ohms.

Preferably, the carrier substrate is provided as a printed circuit board in which, in the manufactured state, the at least one metal layer that is bonded to the ceramic element is structured. For example, it is provided for this purpose that structuring, for example by laser cutting, etching and/or mechanical processing, is also carried out after the bonding step, with which conductor paths and/or connections for electrical or electronic components are realised. Preferably, a further metal layer, in particular a backside metallization and/or a heat sink, is provided on the ceramic element on the side opposite the metal layer on a manufactured metal-ceramic substrate. The backside metallization preferably serves to counteract deflection and the heat sink serves to effectively dissipate heat that is emitted during operation by electrical or electronic components that are bonded to the printed circuit board or the metal-ceramic substrate.

Copper, aluminium, molybdenum, tungsten, nickel and/or alloys thereof, such as CuZr, AlSi or AlMgSi, as well as laminates such as CuW, CuMo, CuAl and/or AlCu or MMC (metal matrix composite), such as CuW, CuM or AISiC, are conceivable as materials for the at least one metal layer and/or a further metal layer in the metal-ceramic substrate or in the interconnection. Furthermore, it is preferably provided that the at least one metal layer on the manufactured metal-ceramic substrate is surface-modified, in particular as component metallisation. Surface modification could be, for example, sealing with a noble metal, in particular silver and/or gold, or (electroless) nickel or ENIG (“electroless nickel immersion gold”) or edge encapsulation on the metallisation to suppress crack formation or expansion.

Preferably, it is provided that a thickness of the bonding layer, in particular of the bonding agent layer, measured in the stacking direction, averaged over a plurality of measuring points within a predetermined area or in a plurality of areas that run parallel to the main extension plane, has a value that is less than 20 μm, more preferably less than 10 μm and most preferably less than 6 μm. Where the term “several areas” is used, it is meant in particular that the at least one metal layer is subdivided into areas of as equal a size as possible and at least one value, more preferably several measured values, for the thickness are recorded in each of these areas subdividing the at least one metal layer. The thicknesses determined in this way at different points are arithmetically averaged.

In particular, it is provided that the interconnection comprises the bonding layer and/or a further bonding layer, wherein a bonding agent layer of the further bonding layer has a sheet resistance which is greater than 5 ohm/sq, more preferably greater than 10 ohm/sq, and most preferably greater than 20 ohm/sq. In other words: Preferably, the bonding layer with the comparatively high sheet resistance extends on an inner side of the recess and thereby forms at least part of the interconnection and/or the bonding layer is used for bonding metal for forming the interconnection. If, for example, a different solder base material is used for forming the interconnection, a further bonding layer different from the bonding layer can be formed. It is particularly advantageous that, for example, the active metal can be deposited on the top or bottom side of the ceramic element and the side surfaces of the recess in a common process step. In other words, it is not necessary to apply an additional bonding agent. Preferably, the bonding agent layer for forming the bond between the at least one metal layer and the ceramic element extends into the recess to form the interconnection.

Preferably, it is provided that, in a sectional view running parallel to the main extension plane, the interconnection and/or a recess in the ceramic element has a cross-section whose shape deviates from a circle. It has been found that by adapting the geometry accordingly, it is advantageously possible to influence the thermal shock resistance of the substrates, especially in the area of the recesses or interconnections. In particular, a tendency to crack formation can be reduced here. The areas of the interconnections are subject to increased stresses in terms of thermomechanical stresses when heat is generated on the component side during operation. Appropriate geometric shapes can contribute to localised relief. It is conceivable that star-shaped, point-shaped, labyrinth-like, arc-shaped, polygonal, elliptical or other cross-sections can be used to influence the thermal shock resistance. Preferably, the interconnection area comprises web-like subsections formed by the ceramic element. In particular, it has proven to be particularly advantageous to form rounded corner areas in the interconnection, for example in the form of an elongated hole that is recessed into the ceramic element. The recess can be realised in the ceramic element, for example by punching or removing a subregion in the green body, i.e. before the ceramic element hardens. However, it is also conceivable that a subregion of the (sintered) ceramic element is removed again, for example by means of a mechanical, chemical and/or optical process, for example by means of a laser, etching or milling process.

Furthermore, it is conceivable that an arrangement of several interconnections is formed to be a parallel circuit thereof. In other words, an arrangement of several interconnections replaces the previous, large-area interconnection. For this purpose, it is provided that, for example, at least 40 interconnections/cm², more preferably at least 90 interconnections/cm² and most preferably at least 140 interconnections/cm² are formed in order to form a corresponding arrangement. This arrangement is particularly advantageous in terms of reliability because cracks due to thermal stresses can only propagate to the next interconnection. In this way, for example, the reliability of an interconnection area can also be increased, as the failure of a single interconnection may not make the requirement no longer suitable to operate the metal-ceramic substrate.

The arrangement of interconnections can follow a geometric specification or be formed randomly in the ceramic element in a subsection of the ceramic element. In other words, regular or irregular arrangements can be provided. In particular, the arrangement of interconnections forms a convex hull, i.e. a subset containing the smallest convex set that contains the initial set. For example, the convex hull is repeated several times on the metal-ceramic substrate. However, it can also be just a single convex hull. The area enclosed by the convex envelope is determined by the arrangement of the recess within the convex envelope and is determined in particular by the minimum area of the shape comprising all interconnections of the arrangement. In addition, the arrangement can preferably be designed in such a way that it can in turn influence the thermomechanical fatigue resistance of the overall substrate, i.e. the metal-ceramic substrate. Preferably, the arrangement of interconnections occupies an area, in particular in the form of a convex envelope, of more than 4 mm², more preferably more than 9 mm² and most preferably more than 16 mm².

Furthermore, it is provided that a recess in the ceramic element has a side surface which surrounds the interconnection at least in sections or completely, wherein the side surface is along a direction running parallel to the stacking direction(S), curved at least in sections and/or inclined to the stacking direction. This therefore relates to the side surfaces within the ceramic element and not to the top and bottom sides of the ceramic element, which in each case face the component and/or the backside metallisation, or not to the surrounding outer side of the ceramic element. These side surfaces can be curved or, for example, form an angle to the stacking direction that is greater than 5°, more preferably greater than 10° and most preferably greater than 20°. In particular, the angle has a value between 0° and 45°, more preferably between 2° and 30° and most preferably between 5° and 15°. This simplifies in particular the pressing in of the component metallisation and backside metallization as part of the bonding process using hot isostatic pressing. In addition, a correspondingly inclined course simplifies the application of the active metal and/or the solder base material by means of gas-physical deposition, as this simplifies access to the side surfaces.

Preferably, it is provided that the recess is only partially filled, wherein a ratio of a first volume of the recess filled with a conductive material to a second volume limited by the entire recess has a value between 0.05 and 0.8, more preferably between 0.055 and 0.5 and most preferably between 0.05 and 0.20. It has been found that it is even possible to ensure interconnection with a comparatively low filling that fulfils the operating requirements of the metal-ceramic substrate. In particular, it is possible for the interconnection to be formed exclusively by the active metal layer and the solder base layer, which then become the bonding layer in the bonding process. In this case, the ratio of the first volume to the second volume is preferably less than 0.3, more preferably less than 0.2 and most preferably less than 0.15. Furthermore, it is preferably provided that the interconnection in the manufactured metal-ceramic substrate has a porosity whose proportion, i.e. the sum of the volumes of the individual pores, to the total volume of the interconnection has a value which is less than 0.3, more preferably less than 0.1 and most preferably less than 0.01. For example, the proportion of porosity to the total volume of the interconnection has a value between 0 and 0.2, more preferably between 0 and 0.05 and most preferably between 0 and 0.02. In particular, porosity means the proportion of pores in the formerly molten phase that wets the inside of the recess. The comparatively low porosity enables more uniform conductivity and improved bonding to the inside of the recess. If a solder base layer is provided in addition to an active metal layer to form the bonding layer, the solder base layer preferably comprises an Ag or Cu alloy. As a result, a solder base material with a low specific resistance is used in the joining process, thus resulting in a low resistance in the interconnection produced.

It is also conceivable that the interconnection has a different material composition than the bonding layer between the component metallisation and/or backside metallization. For example, a different solder base material can be used for the interconnection and the bonding of the metal layer. For this purpose, the ceramic element provided with the recess is immersed in a molten metal of Cu, In and/or Al, for example. Preferably, it is provided that an electrical resistance of one interconnection or several interconnections, preferably connected in parallel, has a value between 10 μOhm and 10 mOhm, more preferably between 100 μOhm and 2 mOhm and most preferably between 250 μOhm and 1 mOhm. Furthermore, it is preferably provided that the area-normalised electrical conductance of a interconnection or matrix of several interconnections or the arrangement of interconnections related to the convex envelope has a value of >50 kS/cm², more preferably >150 kS/cm² and most preferably >300 kS/cm².

Preferably, it is provided that the conductive material of the interconnection is formed by the metal layer, which is in particular at least partially moulded into the recess. This occurs in particular during the production of the interconnection as part of hot isostatic pressing, in which the component metallisation and/or backside metallization is forced into the recess due to the high pressure. In this case, a bulge forms on the outer side of the component metallisation and/or backside metallisation, in particular on the surface side facing away from the ceramic element. The recess in the ceramic element is preferably completely filled. Due to the large conductor cross-section, comparatively low electrical resistances can be realised for the interconnection. In addition, the interconnection is formed by the component metallisation or the backside metallization, which have a low specific resistance due to their material and purity.

In particular, it is provided that the interconnection is formed as a through-hole metallisation covering the side surface (SF) of the recess, the inner diameter of which has a value between 0.1 and 2 mm, more preferably between 0.2 and 1 mm and most preferably between 0.3 and 0.6 mm. This realises a comparatively large free volume in the interconnection. Preferably, the interconnection is formed by the bonding layer and/or the further bonding layer, in particular exclusively by the bonding layer and/or the further bonding layer.

Preferably, it is provided that a surface area ratio of the side surfaces limiting the recess covered by a conductive material to the total surface area of the side surfaces limiting the recess has a value which is greater than 0.8, more preferably greater than 0.9 and most preferably greater than 0.95. A conductive layer is thus formed in particular on the inside of the recess (for example by the bonding layer, which is also provided for bonding the metal layer to the ceramic element), which contributes to the interconnection forming a conductive joining between the upper side and bottom side of the ceramic element. For example, the interconnection provides an empty volume in the centre, which is surrounded by the inner coating of the recess for forming the interconnection.

A further object of the present invention is a method of manufacturing a metal-ceramic substrate according to the invention, whereby the advantages and properties of the metal-ceramic substrate can be transferred analogously to the method for its manufacture and vice versa. In particular, it is provided that the interconnection is produced at the same time as the bonding of the component metallisation and/or backside metallization to the ceramic element. Preferably, it is provided that the bonding of the ceramic element to the component metallisation and/or backside metallisation is carried out as part of hot isostatic pressing and/or with the use of a solder system with a separate active metal layer. In particular, it is provided that the interconnection is formed without a separate metal element, which would fill the recess in the manufactured state. In other words, only metal layers that are bonded to the upper side and/or bottom side of the ceramic element are used in the production of the interconnection.

In particular, a ceramic element is provided with a recess in which the interconnection is realised, preferably at the same time or overlapping in time with the bonding of the at least one metal layer to the ceramic element. The active metal layer has an active metal content of more than 15 weight percent, more preferably more than 40 weight percent and most preferably more than 70 weight percent.

The active metal is preferably applied by means of a gas-physical or chemical method, for example a PVD, CVD or PECVD method, to form the active metal layer. Galvanic, electroless and/or thermal application or application by cold gas spraying is also conceivable.

Preferably, it is provided that the side surfaces of the recess are covered with an active metal layer at least in sections. This makes it possible in an advantageous manner to provide a bonding layer or active metal layer that is as homogeneous and comparatively thin as possible, from which in turn the corresponding bonding layer with sheet resistances that are greater than 5 ohm/sq, more preferably greater than 10 ohm/sq and most preferably greater than 20 ohm/sq, is produced as part of the bonding process.

For example, it is envisaged that a method for the production of a metal-ceramic substrate is provided, comprising:
Providing a solder layer, in particular in the form of at least one solder foil or brazing foil,
coating the ceramic element, in particular an inner side of a recess of the ceramic element, and/or the at least one metal layer and/or the at least one solder layer with at least one active metal layer,
arranging the at least one solder layer between the ceramic element and the at least one metal layer along a stacking direction, forming a solder system comprisesing the at least one solder layer and the at least one active metal layer, wherein a solder material of the at least one solder layer is preferably free of a melting point lowering material or of a phosphorus-free material, and
bonding the at least one metal layer to the at least one ceramic layer via the soldering system by means of an active soldering process.

In particular, a multi-layer soldering system consisting of at least one soldering layer, preferably free of elements lowering the melting point, preferably a phosphorus-free soldering layer, and at least one active metal layer, is provided. The separation of the at least one active metal layer and the at least one solder layer proves to be advantageous in particular because comparatively thin solder layers can be realised as a result, in particular if the solder layer is a foil. Otherwise, comparatively large solder layer thicknesses must be realised for active metal-containing solder materials due to the brittle intermetallic phases or the high modulus of elasticity and high yield strength of the common active metals and their intermetallic phases, which hinder the forming of the solder paste or solder layer, thus limiting the minimum layer thickness due to the manufacturing properties of the active metal-containing solder material. Accordingly, it is not the minimum thickness required for the joining process that determines the minimum solder layer thickness of the solder layer for active metal-containing solder layers, but rather the minimum layer thickness of the solder layer that can be technically realised determines the minimum solder layer thickness of the solder layer. As a result, this thicker, active metal-containing solder layer is more expensive than thinner layers. By phosphorus-free, the skilled person understands in particular that the proportion of phosphorus in the solder layer is less than 150 ppm, less than 100 ppm and most preferably less than 50 ppm.

Preferably, the solder layer, in particular the phosphorus-free solder layer, comprises several materials in addition to the pure metal. For example, indium is a component of the solder material used in the solder layer.

Furthermore, it is conceivable that the solder material for forming the solder layer is deposited on the active metal layer and/or the at least one metal layer by physical and/or chemical vapour deposition and/or electroplating. This makes it possible in an advantageous way to realise comparatively thin solder layers in the soldering system, in particular in a homogeneous distribution.

For example, in the production of the metal-ceramic substrate, in particular the metal-ceramic substrate, a method is provided comprising:
Providing a ceramic element and a metal layer,
providing a gas-tight container enclosing the ceramic element, wherein the container is preferably moulded from the metal layer or comprises the metal layer,
forming the metal-ceramic substrate by bonding the metal layer to the ceramic element by means of hot isostatic pressing,
   wherein an active metal layer or a contact layer comprising an active metal is arranged at least in sections between the metal layer and the ceramic element to support the bonding of the metal layer to the ceramic element in order to form the metal-ceramic substrate. Preferably, the active metal layer or a contact layer comprising an active metal is also formed on the inside of the recess. The container is preferably formed as a metal container from a metal layer and/or a further metal layer. Alternatively, it is also conceivable that a glass container is used.

In hot isostatic pressing, bonding is provided in particular by heating under pressure, in which the first and/or second metal layer of the metal container, in particular the later metal layer of the metal-ceramic substrate and any eutectic layer occurring there, does not pass into the melting phase. Accordingly, lower temperatures are required for hot isostatic pressing than for a direct metal bonding method, in particular a DCB method.

Compared to the bonding of a metal layer to a ceramic layer by means of a solder material, in which temperatures below the smelting temperature of the at least one metal layer are usually used, the present procedure can advantageously dispense with a solder base material and only an active metal is required. The use or utilisation of pressure during hot isostatic pressing also proves to be advantageous because air inclusions or cavities between the first metal layer and/or the second metal layer on the one hand and the ceramic element on the other hand can thus be reduced, and the frequency of voids forming in the formed or manufactured metal-ceramic substrate can thus be reduced or even avoided. This has an advantageous effect on the quality of the bond between the metal layer or the first and/or second metal layer of the metal container and the ceramic element. In addition, it is advantageously possible to simplify the “second etching” and avoid solder residues and silver migration.

It is also conceivable that an additional solder material is introduced between the ceramic element and the at least one metal layer during hot isostatic pressing, wherein a smelting temperature of the additional solder material can be lower than the temperature at which the hot isostatic pressing is performed, i.e. lower than the smelting temperature of the at least one metal layer.

Preferably, it is provided that during hot isostatic pressing the metal container is subjected to a gas pressure of between 100 and 2000 bar, more preferably between 150 and 1200 bar and most preferably between 300 and 1000 bar and a processing temperature of 300° C. up to a smelting temperature of the at least one metal layer, in particular up to a temperature below the smelting temperature. It has advantageously been found that it is thus possible to bond a metal layer, i.e. a first and/or second metal layer of the metal container, to the ceramic element without the required temperatures of a direct metal bonding method, for example a DCB or a DAB method, and/or without a solder base material used in active soldering. In addition, the use or application of a corresponding gaseous pressure makes it possible to produce a metal-ceramic substrate that is as void-free as possible, i.e. without gas inclusions between the metal layer and the ceramic element. In particular, process parameters are used which are mentioned in DE 2013 113 734 A1 and to which explicit reference is hereby made.

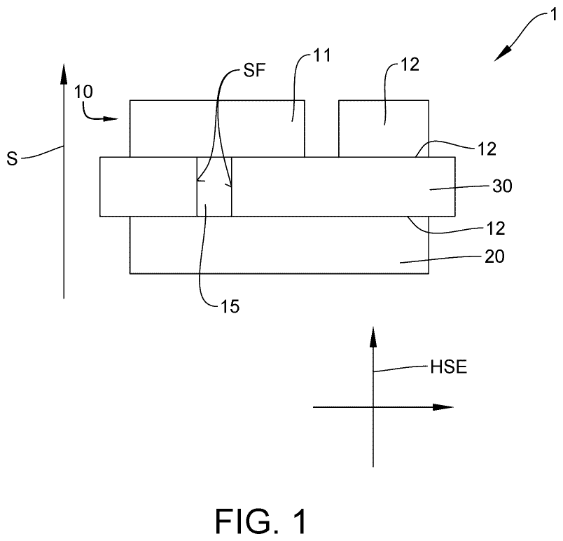

FIG. 1 schematically shows a metal-ceramic substrate 1 according to the prior art. Such a metal-ceramic substrate 1 is preferably a carrier for electrical components. In particular, it is provided that the metal-ceramic substrate 1 has a ceramic element 30 and a component metallisation 10, wherein the ceramic element 30 and the component metallisation 10 extend along a main extension plane HSE. The component metallisation 10 is bonded to the ceramic element 30, wherein the component metallisation 10 and the ceramic element 30 are arranged on top of one another in a stacking direction S perpendicular to the main extension plane HSE. In particular, it is provided that the component metallisation 10 has a plurality of metal sections, for example a first metal section 11 and a second metal section 12, which are arranged, for example, electrically insulated from one another and next to one another along a direction running parallel to the main extension plane HSE.

In particular, it is common in the prior art to first bond the component metallisation 10 to the ceramic element 30, in particular by means of a direct metal bonding process and/or an active soldering process or AMB process and/or an ADB process and/or hot isostatic pressing. Such bonding processes are high-temperature processes in which the arrangement of ceramic element 30 and component metallisation 10 is exposed to an elevated temperature, in particular temperatures above 500° C. After the bonding process, structuring is then carried out, for example by means of an etching process, in order to realise electrically insulated metal sections, in particular a first metal section 11 and a second metal section 12, which can be used as conductor paths and/or connecting areas, so-called pads, for electrical circuits.

On the side of the ceramic element 30 opposite the component metallization 10, a backside metallization 20 is preferably bonded, which is bonded to the ceramic element 30 in particular at the same time, i.e. in a common work step, as the component metallization 10. Alternatively, the component metallization 10 and the backside metallization are bonded one after the other. Such a backside metallization 20 serves in particular to compensate for thermomechanical stresses in the metal-ceramic substrate 1, which are caused by the different thermomechanical expansion coefficients of the component metallization 10 and the ceramic element 30.

In this context, it is provided that the component metallisation 10 comprises at least a first metal section 11 and a second metal section 12. The first metal section 11 and the second metal section 12 are separated from one another after structuring in order to form corresponding conductor paths and/or connecting areas that are electrically insulated from one another. For this purpose, structuring is embedded in the component metallization 10, for example by a chemical method and/or a mechanical method and/or an optical method, wherein a recess in the component metallization 10 necessary for the structuring extends at least as far as the ceramic element 30 in order to provide the necessary electrical insulation. Such isolation sections are formed in particular in the form of trenches in the component metallization 10 and are also known colloquially as isolation trenches.

In order to provide the desired symmetry between a component side and a backside of the metal-ceramic substrate 1, thus allowing corresponding thermomechanical stresses that occur in the metal-ceramic substrate 1 to compensate for each other, it is provided that the backside metallization 20 and the component metallization 10 have essentially a comparable thickness. The thicknesses are measured along a direction following the stacking direction S.

With such metal-ceramic substrates 1, it is also common, for example, to provide interconnections 15 in the ceramic element 30 so that the component metallization 10 can be in electrical contact with the backside metallization 20. As a result, the backside metallization 20 can also be used to conduct a current, for example, in particular to compensate for any parasitic induction effects. Typically, recesses are made in the ceramic element 30 for this purpose, for example by laser light or by drilling, into which in turn a preferably cylindrical piece of metal is embedded, which in turn is bonded to side surfaces SF of the ceramic element 30 in the area of the recess that was embedded in the ceramic element 30.

In contrast to the prior art, it is provided in the present case to link the forming of the interconnection 15 with certain manufacturing processes by which the component metallization 10 or the backside metallization 20 is bonded to the ceramic element 30. In particular, such bonding processes are used which result in a bonding layer 12 with a sheet resistance greater than 5 ohm/sq, more preferably greater than 15 ohm/sq and most preferably greater than 20 ohm/sq, being formed between the component metallization 10 and the backside metallization 20 on one side and the ceramic element 30 on the other side. For example, these are bonding methods in which a separate active metal layer is arranged between the component metallization 10 or the backside metallization 20, and the ceramic element 30. By means of hot isostatic pressing or with the use of a solder base material, which is used in addition to the separate active metal layer, it is then possible to perform a bonding process that leads to the desired sheet resistance, provided that the surface roughness values of the ceramic element and/or the purity of the active metal layer are appropriate. It has been found that the use of such methods in particular means that the costly insertion of a metal piece and a usually multi-stage bonding process is no longer necessary in order to realize an interconnection 15 that meets the requirements necessary in operation, i.e. provides a reasonable electrical resistance and sufficient thermal shock resistance.

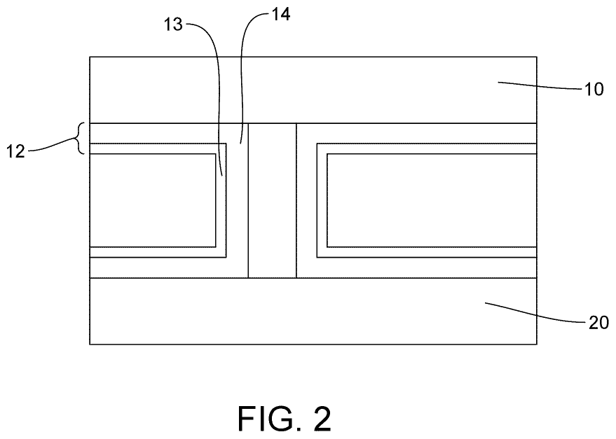

FIG. 2 schematically and exemplarily shows a metal-ceramic substrate 1 with interconnection 15 according to an embodiment of the present invention. In particular, this is an embodiment in which a bonding layer 12 is produced between the component metallization 10 or backside metallization 20 and the ceramic element 30 by providing the ceramic element 30 with an active metal layer 13 and arranging a solder base layer 14 between the component metallization 10 or backside metallization 20 to be bonded and the active metal layer 13. The active metal layer 13 preferably has more than 15 weight percent, more preferably more than 20 weight percent, and most preferably more than 60 weight percent, active metal and is thus not to be understood as a solder layer containing active metal. It is most preferably provided that the active metal layer 13 is deposited on the ceramic element 30 by a gas-physical deposition process, in particular also on the side surfaces SF which limit the recesses in the ceramic element 30. This makes it possible to realize an active metal layer 13 that is distributed as homogeneously as possible and applied comparatively thinly, in particular also in the area of the side surfaces 15 of the recesses. The solder base layer 14 can also be deposited on the active metal layer by a gas-physical deposition process and/or by a dipping process and/or by a screen printing process and/or by another deposition process. It is also conceivable that the active metal layer 13 and/or the solder base layer 14 are applied as a foil or are provided as such. In particular, it has been found that the corresponding bonding process realizes an interconnection 15 in which the recesses have a comparatively large free volume.

In particular, it has been found that it is possible to realize an interconnection 15 by these methods in which a first volume filled by a conductive material to a second volume of the entire recesses has a value which is less than 0.4, more preferably less than 0.3 and most preferably less than 0.2. In this way, it is advantageously possible to realize a sufficient interconnection 15 which meets the requirements for forming an interconnection 15 which satisfies the operating conditions.

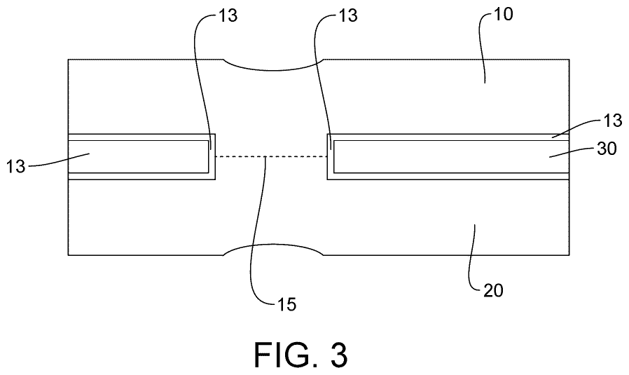

FIG. 3 shows a metal-ceramic substrate 1 with an interconnection 15 according to a furthe embodiment of the present invention. In particular, it is provided that the interconnection 15 shown here is the result of forming a bonding process of a component metallization 10 and/or a backside metallization 20 to the ceramic element 30 by means of hot isostatic pressing. For this purpose, it is provided that an active metal layer 13 is arranged between the component metallization 10 or backside metallization 20 to be bonded and the ceramic element 30. The hot isostatic pressing, in particular the pressure applied and acting on the metal-ceramic substrate 1, then presses part of the component metallization 10 or the backside metallization 20 into the recess formed, in particular in such a way that the component metallization 10 and the backside metallization 20 come into contact with each other. This creates an electrical contact between component metallization 10 and backside metallization 20. Here, too, it is not necessary for an additional work step to be incorporated in order to realize the interconnection 15. On the formed metal-ceramic substrate 1, a dent-shaped recess is formed on the outer surface side of the component metallization 10 or the backside metallization 20, which can be used, for example, to easily find the location of an interconnection 15 in a manufactured metal-ceramic substrate 1.

For example, such a recess or dent can also be used to identify the position of the metal-ceramic substrate 1 as part of the manufacturing process. After all, this is a visually recognizable feature on the outer side of the metal-ceramic substrate 1.

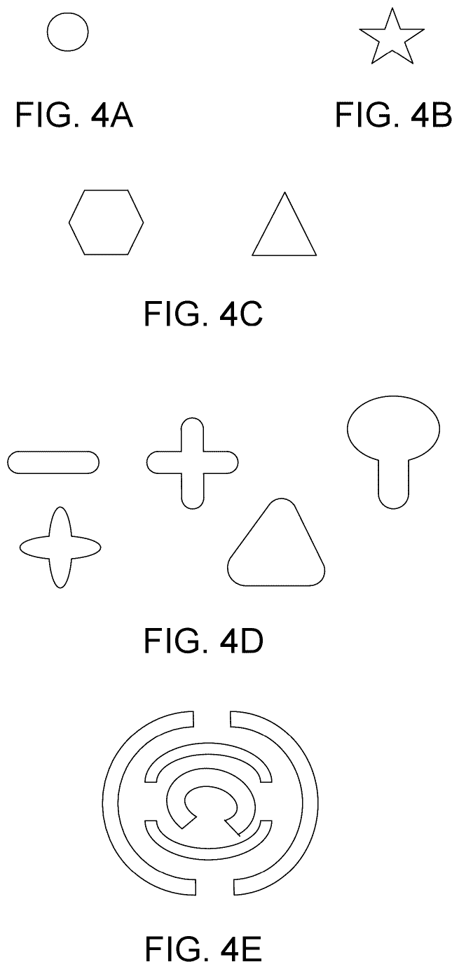

FIGS. 4a to 4e show embodiments of shapes for the recesses which can be recessed in the ceramic element 20 and in which the interconnection 15 is realized. In particular, these are cross-sectional geometries that are formed along a plane running parallel to the main extension plane. In addition to the usual circular cross-section as shown in FIG. 4a, for example, it is also conceivable, for example, to incorporate a star-shaped course for the recesses in the ceramic element 20 (see FIG. 4b). In principle, any polygonal embodiments of the cross-sections are also conceivable, as indicated in FIG. 4c. These include square, rectangular, hexagonal and triangular cross-sections. FIG. 4d indicates that, in particular, rounded geometries are possible, in which, for example, side surfaces SF in the recess that meet at an angle are avoided. In particular, the adaptation of the geometry of an interconnection 15 proves to be advantageous for thermal shock resistance, as in this way relief for otherwise occurring thermomechanical stresses can be prevented. It is also conceivable that the recess is formed as a system of several geometric shapes. For example, FIG. 4e shows the forming of a recess complex in which several arc-shaped sections, or arc segment sections, are arranged labyrinth-like to one another. Preferably, at least a first and a second arcuate section are offset from each other by an angle of between 80 and 120°, preferably by about 90°. For example, it is envisaged that a corresponding recess complex provides bar-like connecting elements which are formed within the recess complex.

Furthermore, it is conceivable that the geometry of the recesses is not completely filled with metal or a conductive material for forming the interconnection 15. For example, it is conceivable that the conductive material within the recess for forming the interconnection 15 has a different geometry than the cross-sectional geometry that the recess has in a plane running parallel to the main extension plane HSE.

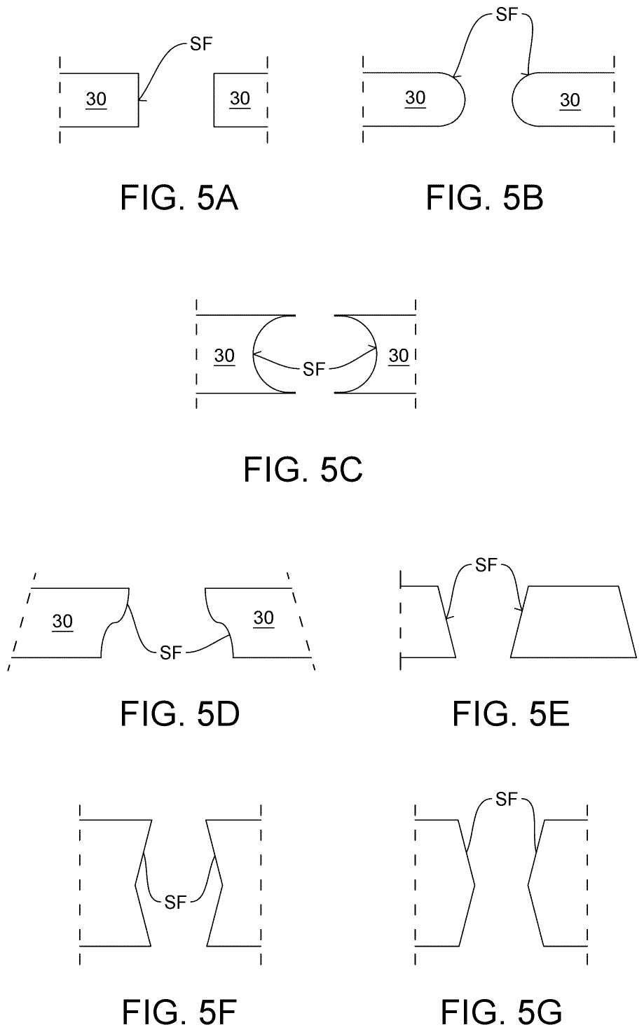

FIG. 5a show shapes or courses for side surfaces SF of the recess in the ceramic element 30. In FIG. 5a, the recess is essentially cylindrical, so that side surfaces SF are formed which run essentially perpendicular to the main extension plane HSE or parallel to the stacking direction S. In FIG. 5b, an embodiment is provided in which the side surfaces SF are rounded. The side surfaces SF can be concave or convex. It is also conceivable that a recess provides both a convex and a concave side surface SF. For example, a design with the convex bulge shown in FIG. 5b proves to be particularly advantageous for the production of the interconnection during hot isostatic pressing, as this makes it easier to force the component metallization 10 into the recess during the pressing process.

In principle, however, any curved geometry of the side surfaces SF of the recesses is also conceivable, as shown for example in FIG. 5d. A conical or frustoconical design, such as that shown in FIG. 5e, is most preferably used, especially for forming during hot isostatic pressing. In particular, forming with a simple frustoconical course results in the metallization on the open side being pressed further into the recess during hot isostatic pressing than the metal layer on the opposite side, so that an asymmetry is created or caused with regard to the proportion of the metallization that is provided by the component metallization or the backside metallization for the interconnection. In contrast, in FIG. 5g it is provided that two frustoconical courses are provided, i.e. a double frustoconical course, which in particular allows metal to be pressed from both sides to the same extent into the recess for forming the interconnection 15. In FIG. 5f, an embodiment example is shown in which the side surfaces SF are aligned in such a way that the smallest diameter of the recess, measured in a plane running parallel to the main extension plane, is formed on the top and bottom side of the ceramic element 30.

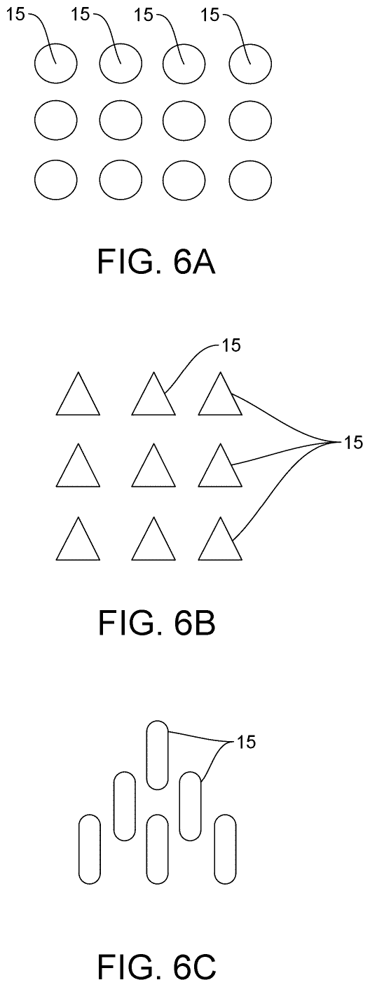

FIGS. 6a to 6c show arrangements of interconnections 15. In particular, it is conceivable that instead of an interconnection 15, an arrangement of comparatively many small recesses with a correspondingly embedded interconnection 15 is realized. In particular, it is envisaged that at least 40 recesses/cm², more preferably at least 90 recesses/cm², most preferably more than 140 recesses/cm² are provided for such an arrangement. The example shown in FIG. 6a is an arrangement that is essentially rectangular. The triangles shown in FIG. 6b form a square-shaped surface. The slotted holes shown in FIG. 6c together form a triangular surface as an arrangement.

### REFERENCE SYMBOLS

1 Metal-ceramic substrate
10 Component metallisation
12 Bonding layer
13 Active metal layer
14 Solder base layer
15 Interconnection
20 Backside metallization
30 Ceramic element
SF Side surface
S Stacking direction
HSE Main extension plane

1. A metal-ceramic substrate (1) as a carrier for electrical components, comprising
a ceramic element (30) and
at least one metal layer (10, 20), wherein the at least one metal layer (10) and the ceramic element (30) extend along a main extension plane (HSE) and are arranged on top of one another along a stacking direction(S) running perpendicular to the main extension plane (HSE),
wherein a bonding layer (12) is formed in the manufactured metal-ceramic substrate (1) between the at least one metal layer (10, 20) and the ceramic element (30),
wherein a bonding agent layer of the bonding layer (12) has a sheet resistance which is greater than 5 ohm/sq, and
wherein an interconnection (15) is formed in the ceramic element (30).

2. The metal-ceramic substrate according to claim 1, wherein the interconnection (15) comprises the bonding layer (12) and/or a further bonding layer (12), wherein a bonding agent layer of the further bonding layer has a sheet resistance which is greater than 5 ohm/sq.

3. The Metal-ceramic substrate (1) according to claim 1, wherein, in a sectional view running parallel to the main extension plane (HSE), the interconnection (15) and/or a recess in the ceramic element (30) has a cross-section whose shape deviates from a circle.

4. The metal-ceramic substrate (1) according to claim 1, wherein an arrangement of a plurality of interconnections (15) is formed to be a parallel circuit thereof.

5. The metal-ceramic substrate (1) according to claim 1, wherein a recess in the ceramic element (30) provided for the interconnection (15) has a side surface (SF) which surrounds the interconnection (15) at least in sections, wherein the side surface (SF) is along a direction running parallel to the stacking direction(S) curved at least in sections and/or inclined with respect to the stacking direction(S).

6. The metal-ceramic substrate (1) according to claim 1, wherein the recess is only partially filled, wherein a ratio of a first volume filled with a conductive material to a second volume limited by the recess has a value between 0.05 and 0.8.

7. The metal-ceramic substrate (1) according to claim 1, wherein the conductive material of the interconnection (15) is at least partially formed by the at least one metal layer (10, 20).

8. The metal-ceramic substrate (1) according to claim 1, wherein the interconnection (15) is formed as a through-hole metallization covering the side surface (SF) of the recess, the inner diameter of which has a value between 0.1 and 2 mm.

9. A method of manufacturing a metal-ceramic substrate (1) according to claim 1.

10. The method according to claim 9, wherein the side surface (SF) of the recess is covered with an active metal layer at least in sections.
